(19) United States
(12) Patent Application Publication
(10) Pub. No.: US 2007/0273023 A1
(43) Pub. Date: Nov. 29, 2007

(54) Integrated circuit package having exposed thermally conducting body

(75) Inventors: Sam Ziqun Zhao, Irvine, CA (US); Edward Law, Ladera Ranch, CA (US); Rezaur Rahman Khan, Rancho Santa Margarita, CA (US)

Correspondence Address: STERNE, KESSLER, GOLDSTEIN & FOX P.L.L.C., 1100 NEW YORK AVENUE, N.W., WASHINGTON, DC, 20005, US

(73) Assignee: Broadcom Corporation, Irvine, CA (US)

(21) Appl. No.: 11/583,718

(22) Filed: Oct. 20, 2006

Related U.S. Application Data
(60) Provisional application No. 60/808,543, filed on May 26, 2006.

(51) Int. Cl. H01L 23/34

(52) U.S. Cl. 257/706

(57) ABSTRACT

An apparatus and method for a wire-bond die-up area array package is described. The package includes an integrated circuit (IC) die, a substrate, and a thermally conducting body. A bottom surface of the IC die is exposed through an opening in a central region of the substrate. The die is mounted to the thermally conducting body. A bottom surface of the thermally conducting body is configured to be connected to a circuit board, such as a PWB, when the package is mounted to the circuit board. The bottom surface of the thermally conducting body may be connected directly to the circuit board, or may be coupled to the circuit board via solder balls or other mechanism. One or more wirebonds are used to electrically connect the die to a top surface of the substrate. A mold compound encapsulates the die, the wirebonds, and at least a portion of the top surface of the substrate, and fills a gap between peripheral edges of the IC die and inner walls of the substrate central window opening. A matrix of solder balls is attached to a bottom surface of the substrate.

This application claims the benefit of U.S. Provisional Appl. No. 60/808,543, filed May 26, 2006, which is incorporated by reference herein in its entirety.

### BACKGROUND OF THE INVENTION

1. Field of the Invention

The embodiments of the present invention relate to integrated circuit (IC) device packaging technology, and in particular, to ball grid array (BGA) packages having improved thermal and/or electrical characteristics.

2. Related Art

The die-up plastic ball grid array package was first introduced by Motorola and was called Overmolded Plastic Pad Array Carriers (OMPAC). For further detail on this package, refer to “Overmolded Plastic Pad Array Carriers (OMPAC): A Low Cost, High Interconnect Density IC Packaging Solution for Consumer and Industrial Electronics,” Electronic Components and Technology Conference, IEEE, pp. 176-182, 1991, which is incorporated by reference herein in its entirety. Commonly known as a “PBGA” package, the plastic ball grid array (PBGA) package features a plastic printed circuit board (substrate) typically made of Bismaleimide Triazine (BT) resins or FR4 materials.

FIG. 1 shows a conventional PBGA package 100. As shown in FIG. 1, PBGA package 100 has the following features:

a) An integrated circuit (IC) semiconductor die 118 is attached directly to the top surface of a printed circuit substrate 102.

b) Wirebonds 104 are used to electrically connect circuits of IC die 118 to a printed circuit on substrate 102.

c) A matrix of solder balls 110 is attached to the bottom surface of substrate 102.

d) A plastic molding compound 108 encapsulates both IC die 118 and bond wires 104, and covers a portion of the top surface of substrate 102, for environmental protection. A periphery of the surface of substrate 102 around molding compound 108 is exposed (not covered by molding compound 108).

Conventional BGA packages, such as shown in FIG. 1, have drawbacks, including: (1) a high package profile; (2) poor thermal performance; and (3) a long electrical interconnection path between IC die 118 and external pins of the package, and other drawbacks. Thus, what is needed are BGA packages with improved thermal performance, improved electrical performance, reduced package assembly yield loss, and improved package reliability.

### SUMMARY OF THE INVENTION

Apparatuses, methods, and systems for improved integrated circuit packages are described. Embodiments of the present invention provide improved thermal, electrical, and mechanical performance for wire-bond die-up array packages (BGA, PGA, and LGA IC), profile size reduction of these packages, and improvement of package board mount reliability.

In an aspect of the present invention, an integrated circuit ball grid array package includes a planar substrate having a plurality of contact pads on its top surface, electrically connected through the substrate to a plurality of solder ball pads on its bottom surface, and an opening through the substrate. An IC semiconductor die is mounted in the opening of the substrate. A thermally conducting body capable of being attached to a circuit board, such as a printed circuit board (PCB) or printed wiring board (PWB), is connected to the bottom surface of the IC die.

In an aspect, the thermally conducting body is not in direct contact with the substrate. Instead, a gap is present surrounding the IC die and thermally conducting body, between the IC die/thermally conducting body and the substrate opening.

In a further aspect, a wire bond connects a bond pad of the IC die to a contact pad of the substrate. In another aspect, a wire bond connects a bond pad of the IC die to the thermally conducting body.

In a further aspect, a mold compound seals the die, the wire bond(s), covers at least a portion of the top surface of the substrate, and fills the gap. In a further aspect, the mold compound partially covers the bottom surface of the substrate around the periphery of the substrate opening.

In a still further aspect, a plurality of solder balls is attached to the solder ball pads on the bottom surface of the substrate, to connect the package to a circuit board when mounted thereto.

As mentioned above, the thermally conducting body is configured to be attached to a circuit board. In one aspect, a bottom surface of the thermally conducting body is directly connected to the circuit board when the package is mounted thereto. In another aspect, a second plurality of solder balls can be attached to the bottom surface of the thermally conducting body, to couple the thermally conducing body to the circuit board when mounted thereto.

In a further aspect, the thermally conducting body is planar. In another aspect, the thermally conducting body is non-planar. In a first example non-planar aspect, the thermally conducting body has a cavity formed therein, in which the die may be mounted. In another example non-planar aspect, the thermally conducting body is “hat” shaped.

In another aspect of the present invention, a ball grid array package is assembled. A cover film is laminated to a substrate with an opening through the cover film and substrate. A carrier film is laminated on the cover film. A thermally conducting body is attached to the carrier film through the opening of the substrate and cover film. An IC die is attached to the thermally conducting body. Bond pads on the IC die are connected with contact pads on the substrate. Ground/power pads are connected on the IC die with the exposed thermally conducting body. The IC die, wirebond, and opening in the substrate are encapsulated. The carrier and cover films are removed. A matrix of solder balls is attached to the bottom surface of the substrate.

These and other objects, advantages and features should become readily apparent in view of the following detailed description. Note that the Summary and Abstract sections may set forth one or more, but not all, exemplary embodiments of the present invention as contemplated by the inventors.

### BRIEF DESCRIPTION OF THE FIGURES

The accompanying drawings, which are incorporated herein and form a part of the specification, illustrate the embodiments of the present invention and, together with the description, further serve to explain the principles of the embodiments and to enable a person skilled in the pertinent art to make and use the invention.

FIG. 1 shows a conventional plastic ball grid array (PBGA) construction.

FIG. 2 shows a BGA package with a through-cavity opening in the substrate for receiving an exposed die.

FIG. 3 shows a thermally and electrically enhanced die-up tape BGA with a stiffener/interposer and a thermal/electrical connector.

FIG. 4 shows a BGA package with a heat slug having a solderable surface to attach to a PWB.

FIG. 5 shows a BGA package with an integrated circuit (IC) die molded in a central window opening of a package substrate, according to an example embodiment of the present invention.

FIG. 6 shows a BGA package with a thermal connector that connects the BGA to an exposed IC die, according to an example embodiment of the present invention.

FIGS. 7A and 7B show BGA packages with thermal connectors where the side walls of the thermal connectors are respectively partially exposed and completely exposed, according to example embodiments of the present invention.

FIG. 8 shows a BGA package with a matrix of mini-solder balls attached to a thermally conductive body, according to an example embodiment of the present invention.

FIGS. 9A and 9B show non-planar thermally conductive bodies, according to example embodiments of the present invention.

FIG. 10 shows an example of a BGA package that incorporates the thermally conductive body shown in FIG. 9A, according to an example embodiment of the present invention.

FIG. 11 shows a flowchart of the assembly steps for a BGA package, according to an example embodiment of the present invention.

FIG. 12A-12F illustrates a BGA package at different phases of assembly, according to an example embodiment of the present invention.

FIGS. 13A-13G illustrate a BGA package at different phases of assembly, according to an example embodiment of the present invention.

FIG. 14 shows a flowchart of the assembly steps for a BGA package, according to an example embodiment of the present invention.

FIGS. 15A-15E illustrates a BGA package at different phases of assembly, according to an example embodiment of the present invention.

The embodiments of the present invention will now be described with reference to the accompanying drawings. In the drawings, like reference numbers indicate identical or functionally similar elements. Additionally, the left-most digit(s) of a reference number identifies the drawing in which the reference number first appears.

### DETAILED DESCRIPTION OF THE INVENTION

### Introduction

References in the specification to “one embodiment,” “an embodiment,” “an example embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to effect such feature, structure, or characteristic in connection with other embodiments whether or not explicitly described.

The present specification discloses one or more embodiments that incorporate the features of the invention. The disclosed embodiments merely exemplify the invention. The scope of the invention is not limited to the disclosed embodiments. The invention is defined by the claims appended hereto.

Furthermore, it should be understood that spatial descriptions (e.g., “above”, “below”, “left,” “right,” “up”, “down”, “top”, “bottom”, etc.) used herein are for purposes of illustration only, and that practical implementations of the structures described herein can be spatially arranged in any orientation or manner.

### Overview

The embodiments of the present invention described herein provide die-up array package (BGA, PGA, LGA, etc.) having improved thermal, electrical and mechanical performances. The present invention is applicable to all types of BGA substrates, including ceramic, plastic, and tape (flex) BGA packages.

Numerous embodiments of the present invention are presented herein. For example, in an embodiment, an IC die can be molded within a central opening in the substrate with the bottom surface of the die underneath the top surface of the substrate. Because the IC die can be molded within the opening, the mold thickness can be reduced substantially by lowering the elevation of the top surface of the IC die, or even with its bottom surface protruded below the bottom surface of the substrate. Additionally, in an embodiment, the bottom surface of the IC die can be configured for thermal contact with a PWB on which the package is mounted. A direct thermal connection between the bottom surface of the IC die and top of the PWB provides a conductive thermal path from the IC die to the PWB for heat dissipation. Because the height of the IC die can be reduced to be closer to the top surface of the substrate, the length of the wirebond connecting the IC die to the substrate can be reduced.

In an embodiment, a substrate opening window is provided. A semiconductor die is molded in the opening. The mold is exposed from both the top and bottom surfaces of the substrate. Instead of an array of peripheral leads found in leadframe packages, a matrix of solder balls is located on the bottom surface of the substrate surrounding the exposed mold in the central region of the substrate. The IC package is surface mounted on a PWB. A die attach pad couples the bottom surface of the die to the PWB. The bottom surface of the IC die can be further coated with metal or metal alloy to facilitate direct soldering to the PWB.

Because the IC die can be molded within the opening of the substrate, a total height of the package can be substantially decreased by reducing the mold thickness above the substrate. Package junction-to-board thermal resistances can be substantially reduced by soldering the bottom surface of the IC die to the PWB on which the BGA package is surface mounted. Wirebond length can also be reduced by reducing the spacial distance between bond pad on the IC die and the bond finger on the substrate, a result of placing the IC die into the window opening of the substrate.

### Integrated Circuit Package Technology

A ball grid array (BGA) package is used to package and interface an IC die with a printed circuit board (PCB). BGA packages may be used with any type of IC die, and are particularly useful for high speed ICs. In a BGA package, solder pads do not just surround the package periphery, as in chip carrier type packages, but cover the entire bottom package surface in an array configuration. BGA packages are also referred to as pad array carrier (PAC), pad array, land grid array, and pad-grid array packages. BGA packages types are further described in the following paragraphs. For additional description on BGA packages, refer to Lau, J. H., Ball Grid Array Technology, McGraw-Hill, New York, (1995), which is herein incorporated by reference in its entirety.

Die-up and die-down BGA package configurations exist. In die-up BGA packages, the IC die is mounted on a top surface of the substrate or stiffener, in a direction away from the PCB. In die-down BGA packages, the IC die is mounted on a bottom surface of the substrate or stiffener, in a direction towards the PCB.

A number of BGA package substrate types exist, including ceramic, plastic (PBGA), and tape (also known as “flex”). For examples of different types of BGA packages, refer to Hayden, T. F., et al., Thermal & Electrical Performance and Reliability Results for Cavity-Up Enhanced BGAs, Electronic Components and Technology Conference, IEEE, pp. 638-644 (1999), which is incorporated herein by reference. A few example conventional BGA packages are described in the remainder of this section.

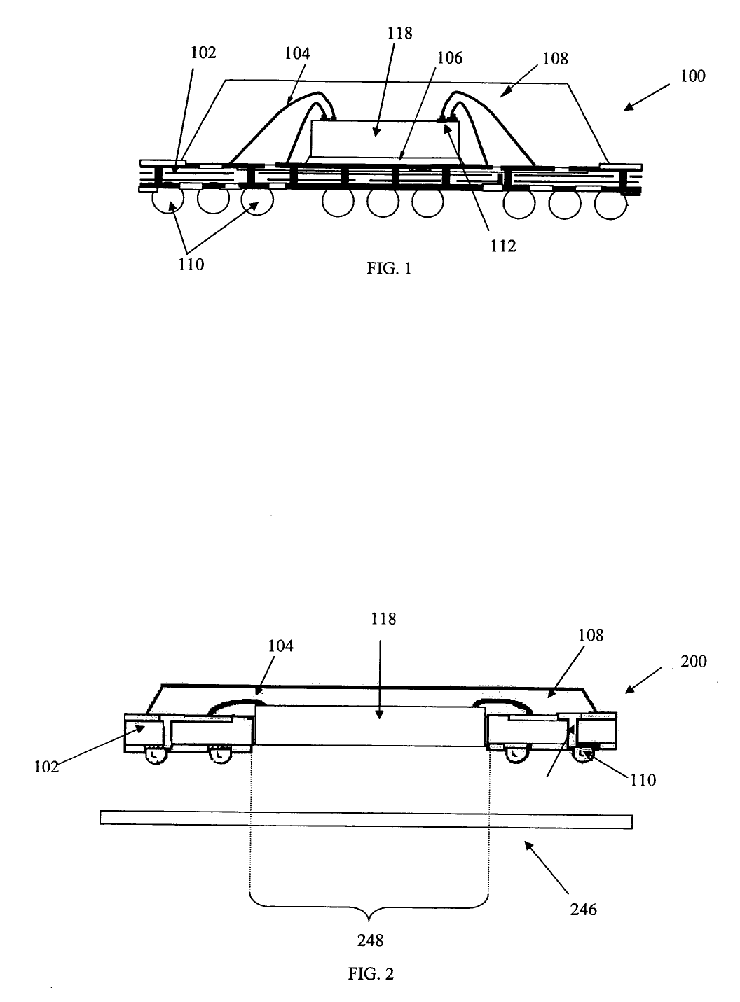

For example, FIG. 2 shows a BGA package 200 including a through-cavity opening 248 in substrate 102 for receiving a semiconductor die 118. For further detail on package 200, refer to U.S. Pat. No. 5,696,666 titled “Low Profile Exposed Die Chip Carrier Package,” which is incorporated by reference herein in its entirety. Package 200 in FIG. 2 reduces package height and improves resistance to moisture sensitivity. Opening 248 has a perimeter that is similar in shape and size to the perimeter of die 118. The rectangular-shaped opening 248 is located near a center of substrate 102, and extends completely through substrate 102. Die 118 is seated in opening 248 such that a bottom surface of IC die 118 is substantially coplanar with a bottom surface of substrate 102. Thus, a typical die-to-substrate interface (where die 118 would be mounted to substrate 102 as in FIG. 1) is eliminated, leaving the bottom surface of IC die 118 exposed.

A transfer molded or glob top material 108 encapsulates the top surface of IC die 118 and portions of the top surface of substrate 102. IC die 118 is held in place by direct and intimate contact between the perimeter of through-cavity opening 248 and the perimeter of IC die 118, and encapsulant-to-die adhesion. The top surface of IC die 118 is at approximately the same level as the top surface of substrate 102. Because the bottom surface of IC die 118 is on the same plane as the bottom surface of substrate 102, exposed die 118 cannot conduct heat directly into the printed wire board (PWB) 246 on which the package is mounted. Additionally, edge walls of substrate 102 directly contact the perimeter of IC die 118. A difference in the coefficient of thermal expansion between substrate 102 and IC die 118 causes thermal stress at the contact interface and can result in cracking of IC die 118 and delamination at the interface.

Another conventional die-up BGA design (not shown) uses a tape substrate, where the bottom surface of the IC die is exposed through the bottom surface of the tape substrate, and the bottom surface of IC die is substantially coplanar with the bottom surface of the tape substrate. For further detail on this package, refer to U.S. Pat. No. 5,506,756 titled “Tape BGA Package Die-up/Die Down,” which is incorporated by reference herein in its entirety. Solder balls are attached to the bottom surface of the exposed IC die to provide additional interconnection between the IC die and the PWB. In another implementation, the active surface of the IC die faces downward (“die-down”) and the bottom surface of the IC die is exposed for a external heat sink attachment to the die from the top side of the package. Because the tape substrate is substantially thinner than the IC die, the top surface of the IC die is well above the top surface of the substrate and the reduction of the package's height is insignificant when the bottom surface of the IC die and the bottom surface of the tape substrate are aligned. Because of the difference in the coefficient of thermal expansion between the IC die and because of the relative softness of tape substrate, the substrate can easily deform from thermal expansion or contraction during the package assembly process. Such a situation can also cause warping in the substrate, and stress at the contact interface around the perimeter of the IC die. Still further, cracks and delamination can originate at this interface and can grow along the perimeter of the IC die.

In the above described packages, both the resin substrate and the plastic molding compound materials have low thermal conductivity values (around 0.19˜0.3 W/m° C. for BT or FR4 type substrates and 0.2˜0.9 W/m° C. for molding compound). Since the IC die is entirely surrounded by materials with poor heat conduction properties, the heat generated by the IC die is trapped within the PBGA package. The temperature of the IC die must rise high above the environment's temperature to release the trapped heat.

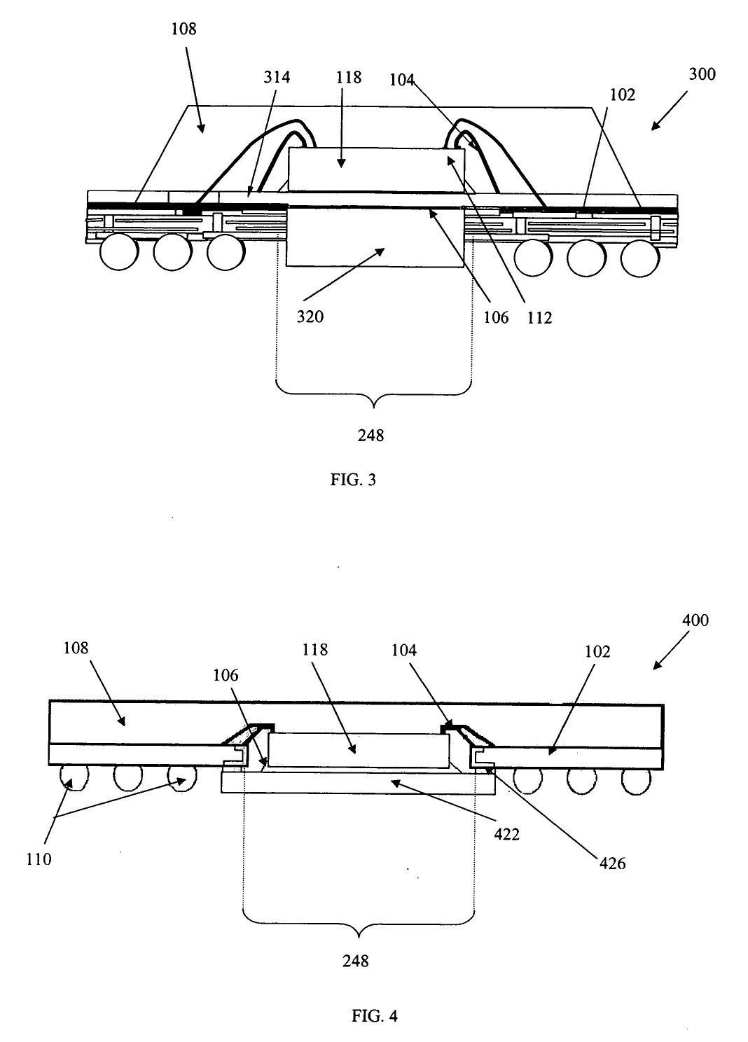

FIG. 3 shows a die-up ball grid array (BGA) package 300 using a copper stiffener/interposer 314 to increase heat transfer from IC die 118 to the rest of package 300. For further detail on package 300, refer to U.S. Patent Appl. Publ. No. 2002/0079562, which is incorporated by reference herein in its entirety. In package 300, the bottom surface of IC die 118 (opposite the integrated circuit on the top surface) is directly attached to a flat copper stiffener 314. The other surface of copper stiffener 314 is attached to substrate 102, which in FIG. 3 is made of an organic material such as a polyimide tape or resin epoxy substrate (BT, for example). Stiffener 314, which may be copper, has a larger surface area than IC die 118 and promotes heat dissipation into the surrounding materials. Connecting the ground pads on IC die 118 to stiffener 314 further reduces package-ground inductance.

A thermally conducting body 320 is attached to stiffener 314 through window opening 248 in substrate 102. Thermally connecting body 320 provides a heat dissipation path from the bottom surface of IC die 118 to the PWB, on which the package is mounted. However, the height or thickness of package 300 is increased due to the requirement of direct IC die attachment on stiffener/interposer 314 that is stacked on package substrate 102.

FIG. 4 shows BGA package 400 with a solderable heat slug for thermal enhancement. For further detail on package 400, refer to “SMT Process Robustness and Board Level Solder Joint Reliability of C2BGA,” 2003 Electronic Components and Technology Conference, pp. 1869-1874, which is incorporated by reference herein in its entirety. Die-up BGA package 400 has a window opening 248 through package substrate 102. A heat slug 422 is attached to a bottom surface of substrate 102 by a solder or electrically conductive adhesive. Heat slug 422 seals window opening 248 from the bottom surface of substrate 102. IC die 118 is attached to heat slug 422 through the window opening 248 in substrate 102.

During a surface-mount process for package 400, heat slug 422 is soldered to a PWB, to achieve low resistance to heat conduction into the PWB. An advantage of package 400 is that a package junction-to-board thermal resistance is reduced and the overall height of the package is reduced with respect to conventional die-up BGA packages. However, to secure a tight seal of the substrate window opening 248, the width of the overlapping area between the heat slug attachment interface along the edges of the substrate window opening 248 and the heat slug periphery should be large. An area of the bottom surface of substrate 102 available to attach solder balls is reduced to make room for the heat slug attachment near the edges of the window opening 248 of substrate 102.

Additionally, heat slug 422 is attached to substrate 102 using a solder or other electrically conductive adhesive that is different from the molding compound used for IC die encapsulation. Two interface triple-lines, contact lines shared by three different materials in contact, are introduced at the opening seal of the substrate window: (1) an interface line between a molding compound 108, substrate 102, and heat slug 422; and (2) an interface line between molding compound 108, IC die 118, and heat slug 422. The difference in the material coefficient of thermal expansion (CTE) and stiffness (or “Yang's modular”) between substrate 102, copper heat slug 422, heat slug attachment material 106, and molding compound 108 makes the interface triple-line prone to stress concentration and related reliability problems including cracking, delamination, and moisture absorption and migration.

Embodiments of the present invention overcome the limitations described above. Example embodiments of the present invention are described in detail below.

### Embodiments According to the Present Invention

Further details of structural and operational implementations of ball grid array packages of the present invention are described in the following sections. These structural and operational implementations are described herein for illustrative purposes, and are not limiting. For instance, the present invention as described herein may be implemented in die-up BGA package types, as well as other IC package types, including land grid array (LGA), pin grid array (PGA), chip scale package (CSP), and quad flat pack (QFP) packages, including any of the BGA packages described above. Furthermore, each of the embodiments presented below are applicable to tape substrate BGA packages, plastic substrate BGA packages, ceramic substrate BGA packages, and other substrate types. The description below is adaptable to these and other package types, as would be understood to persons skilled in the relevant art(s) from the teachings herein.

Features of each of the embodiments presented below may be incorporated into BGA packages independently, or may be combined in any manner with the other features described herein, as would be apparent to persons skilled in the relevant art(s) from the teachings herein.

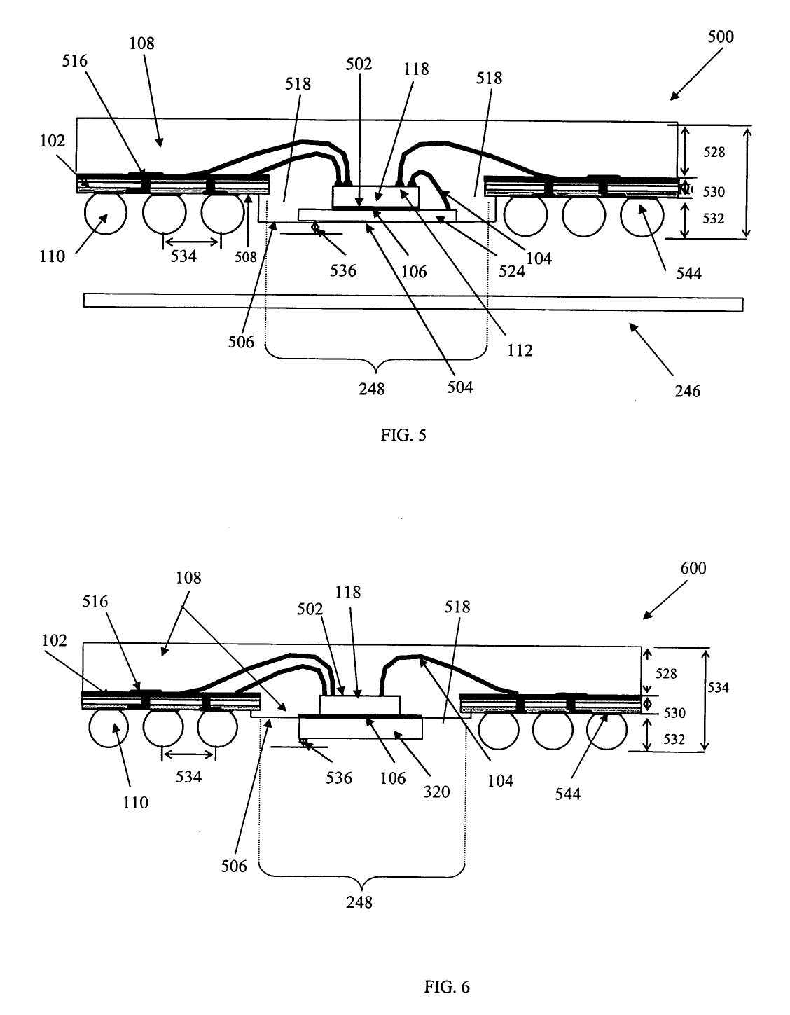

FIG. 5 shows an example of die-up BGA package 500, according to an embodiment of the present invention. Package 500 includes a printed circuit substrate 102 having a window opening 248 in a central region, a thermally conducting body 524, an IC die 118, a plurality of solder balls 110, and an encapsulation mold compound (EMC) 108.

Substrate 102 can be organic (BT, FR4, etc.), ceramic, glass, tape, and/or made from other dielectric materials. Furthermore, substrate 102 may have one or more conductive layers, including features such as contact pads, bond fingers, traces, conductive planes, etc., for transmission of electrical signals, attachment of wirebonds, solder balls, etc., to enhance mounting of electrical components, for power/ground planes, etc. Vias or other electrically conductive features may be used to electrically couple conductive features through substrate 102.

According to an embodiment of the present invention, a bottom surface 502 of semiconductor die 118 is attached to thermally conducting body 524. Thermally conducting body 524 can be made from thermally conductive and/or electrically conductive materials, such as copper, aluminum, nickel, tin, silver, gold, or other metal or combination of metals/alloy, from a ceramic material, a composite material, etc. In an embodiment, thermally conducting body 524 provides an efficient thermally conductive path from die 118 to a circuit board, such as printed wiring board 524, when package 500 is mounted thereto. In another embodiment, thermally conducting body 524 can provide an efficient electrical connection between package 500 and a circuit board, when package 500 is mounted thereto. For example, a signal (e.g., a power or ground signal) of die 118 may be electrically coupled to body 524. Body 524 may be coupled to a conductive feature of the circuit board when mounted thereto, to provide an electrical connection of the signal of die 118 to the circuit board. Furthermore, body 524 may operate as a power or ground plane for package 500 when the signal of die 118 is electrically coupled thereto.

When thermally conducting body 524 is electrically conductive, thermally conducting body 524 can be connected to the ground or power potentials of IC die 118 using one or more wire bonds 104. In such an embodiment, body 524 may also be referred to as an “e-pad” or “electronic pad”.

As shown in FIG. 5, bottom surface 504 of thermally conducting body 524 is exposed (i.e., not covered) at bottom surface 506 of mold compound 108. In an embodiment, bottom surface 504 of exposed thermally conducting body 524 is coated with metal or alloy materials to promote soldering attachment to PWB 246 during the package surface mount process. A standoff height 536 of thermally conducting body 524 is designed such that contact is made between thermally conducting body 524 and PWB 246 after collapse of solder balls 110 on substrate 102. IC die standoff height 536 is configured based on the solder ball size used. For example, a typical standoff height 536 of thermally conducting body 524 is between 0.05 mm and 0.3 mm for packages with an initial solder ball 110 diameter of 0.6 mm, before attachment to package substrate 102. Standoff height 536 may slightly exceed the above range for 0.6 mm diameter balls. However, if standoff height 536 is too small, one or more of solder balls 110 may not make contact with the land pad on PWB 246 after reflow surface mount, causing an open connection. If standoff height 536 is too large, the bottom surface of thermally conducting body 524 may not make contact with PWB 246 due to the limited range over which BGA solder balls 110 can collapse during reflow surface mount.

In embodiments, one or both of die 118 and body 524 reside in opening 248 of substrate 102, depending on the elevation of die 118 and body 524 with respect to substrate 102. Furthermore, body 524 does not make direct contact with substrate 102, but instead is separated from the walls of opening 248 in substrate 102 by a gap 518. Die 118 and body 524 are held in position by mold compound 108. Mold compound 108 seals opening 248 in substrate 102, and covers die 118, wirebonds 104, and a portion of body 524, for environmental protection and structural integrity. Furthermore, mold compound 108 also covers a portion 520 of bottom surface 508 of substrate 102 surrounding opening 248.

Thus, because body 524 does not make contact with substrate 102, the embodiment of FIG. 5 preserves space on a bottom surface 508 of substrate 102 for solder balls. Furthermore, unwanted “interface triple-lines” described above are reduced or eliminated. Still further, body 524 provides an efficient thermal path from die 118 for spreading heat.

In FIG. 5, thermally conducting body 524 is shown wider than IC die 118. Thermally conducting body 524 can alternatively be less wide than IC die 118, or be the same width as IC die 118.

Bottom surface 504 of thermally conducting body 524 can be coated with one or multiple metal films to enhance solder wetting on the surface and promote an interconnection with a circuit board (e.g., PWB 246) during a reflow soldering process. Thermally conducting body 524 can also be connected to PWB 246 using a thermally conductive adhesive.

FIG. 6 shows an example of die-up BGA package 600, according to another embodiment of the present invention. Package 600 is generally similar to package 500 of FIG. 5. with some differences described as follows. Package 600 includes thermally conducting body 320 attached to the bottom surface of IC die 118 but not fully molded in molding compound 108. After mold encapsulation of IC die 118, wirebonds 104, and substrate 102, bottom surface 502 of IC die 118 is exposed and flushed with bottom surface 506 of molding compound 108. Thermally conducting body 320 can be attached to IC die 118 after mold encapsulation using thermally conductive adhesives 106. Alternatively, thermally conducting body 320 can be partially molded with IC die 118 where the side walls of thermally conducting body 320 are partially exposed or completely exposed.

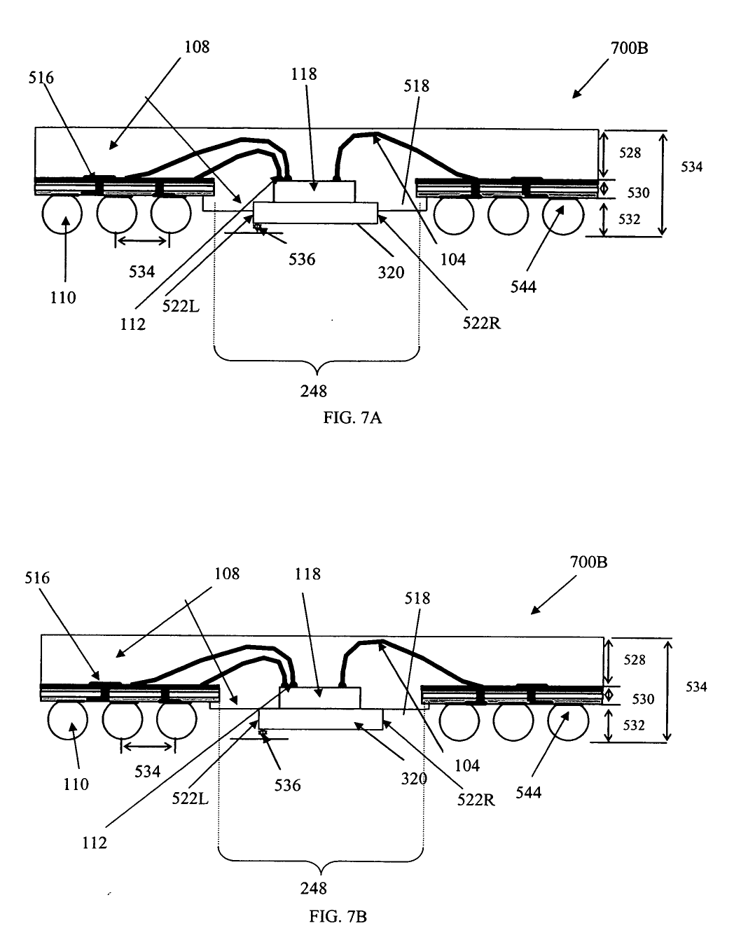

For example, a package 700A shown in FIG. 7A shows partially exposed side walls 522L and 522R (“partially” exposed because the top portion of side walls 522L and 522R penetrate bottom surface 506 of mold compound 108, and are thus covered by mold compound 108). A package 700B shown in FIG. 7B shows side walls 522L and 522R completely exposed (“completely” exposed because neither side wall 522L and 522R penetrates mold compound 108). Thermally conducting body 320 is similar to thermally conducting body 524 shown in FIG. 5, except that thermally conducting body 320 is not electrically coupled to die 118 (e.g., by wirebond), and thus is not considered an “e-pad”. However, in an alternative embodiment, thermally conducting body 320 may be electrically coupled to die 118.

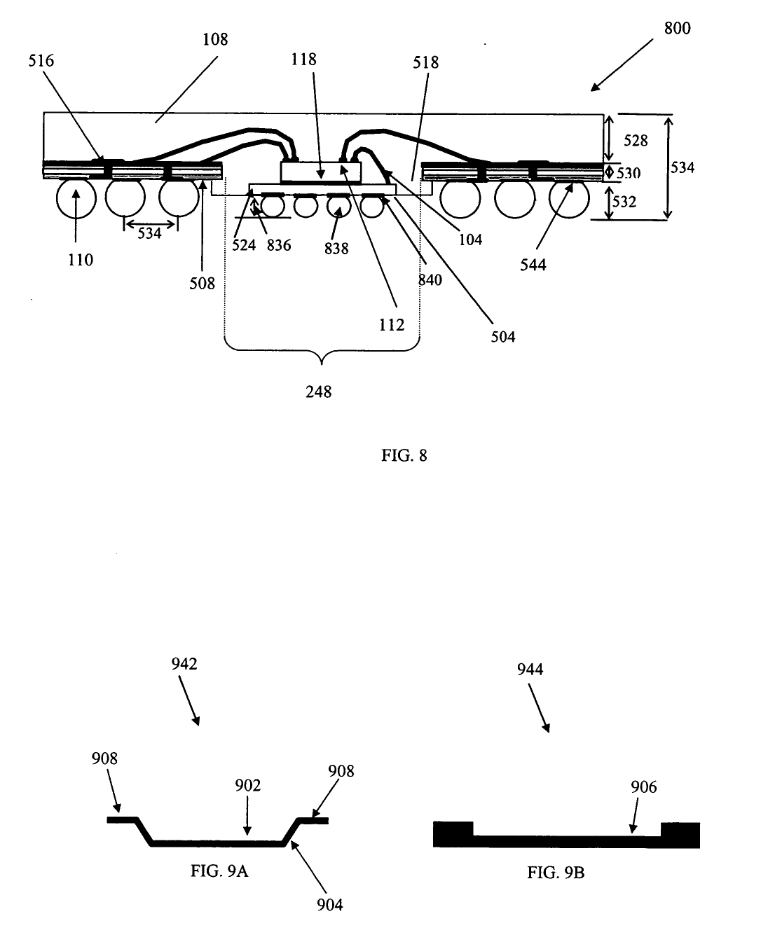

FIG. 8 shows a die-up BGA package 800 with a plurality of mini solder balls 838 attached to bottom surface 506 of exposed thermally conducting body 524, according to an example embodiment of the present invention. Solder balls 838 are attached to exposed bottom surface 506 of thermally conducting body 524. In an embodiment, solder balls 838 are used for ground or power connections between thermally conducting body 524 and a circuit board that mounts package 800. Each of mini solder balls 838 is smaller in diameter than the diameter of large solder balls 110 attached to bottom surface 508 of substrate 102. Mini solder balls 838 also provide a heat conduction path from thermally conducting body 524 to the circuit board. In an embodiment, the edges of mini solder balls 838 that connect to the circuit board are co-planar with the edges of solder balls 110 that connect to the circuit board. The sitting plane for mini solder balls 838 can be slightly closer to thermally conducting body 524 than the sitting plane of large solder balls 110 since the collapse of solder balls 110 is typically greater than that of mini solder balls 838, which lowers mini solder balls 838 on the bottom surface of IC die 118, and allows mini solder balls 838 to contact the circuit board during the reflow process for surface mounting.

For example, in an embodiment, the sitting plane of mini solder balls 838 may be 0.3 mm above the sitting plane of large solder balls 110 attached to substrate 102, because solder balls 110 have diameters of 0.60 mm or larger. The sitting plane for mini solder balls 838 can be slightly farther away from thermally conducting body 524 than the sitting plane of large matrix of solder balls 110 attached to substrate 102 as long as large solder balls 110 can make sufficient contact with ball pads 544 on the circuit board after collapse of mini solder balls 838 during reflow surface mount.

In an embodiment, mini solder balls 838 are attached to contact sites 840 on bottom surface 504 of thermally conducting body 524 defined with selective metal coating. The coating of metal or metal alloy on thermally conducting body 524 promotes solder wetting and helps to define the position of matrix of mini solder balls 838 on thermally conducting body 524.

Thermally conducting body 524 as shown above is substantially planar. However, thermally conducting body 524 can also have other profiles and shapes. FIGS. 9A and 9B show examples of thermally conducting bodies 942 and 944, respectively, which are in shapes other than rectangular or square. For example, in FIG. 9A, thermally conducting body 942 has an inverted cap shape, or “hat” shape, with a cavity 902 on a first surface opposed to a protruding portion 904 on a second surface of thermally conducting body 942. Cavity 902 is surrounded by a planar rim portion 908 of body 942. In FIG. 9B, thermally conducting body 944 is rectangular shaped, has a rectangular cavity 906 formed in a first surface, and has a planar second surface opposed to the first surface. Bodies 942 and 944 can have other shapes, including circular, etc. Furthermore, their surfaces may include structural features for mold locking to secure the body in place, if desired, such as a tab, etc.

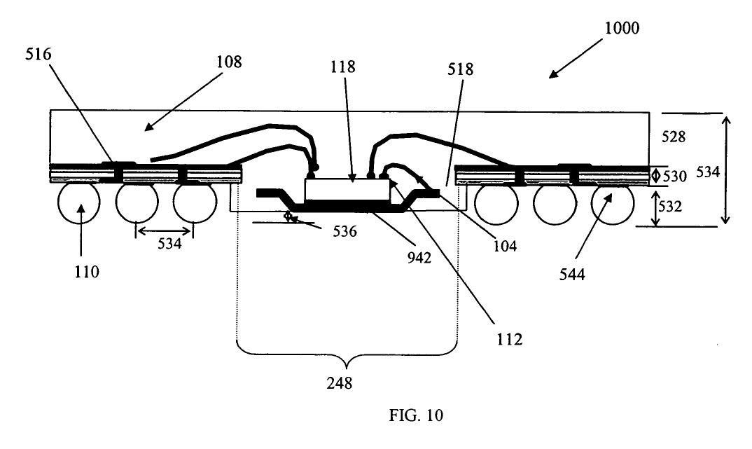

The embodiment in FIG. 10 shows an example of die-up BGA package 1000 including non-planar thermally conducting body 942, according to an embodiment of the present invention. IC die 118 is mounted inside cavity 902 of thermally conducting body 942. Wire bond 104 is attached to rim 908 of thermally conducting body 942 for ground or power connection between IC die 118 and thermally conducting body 942.

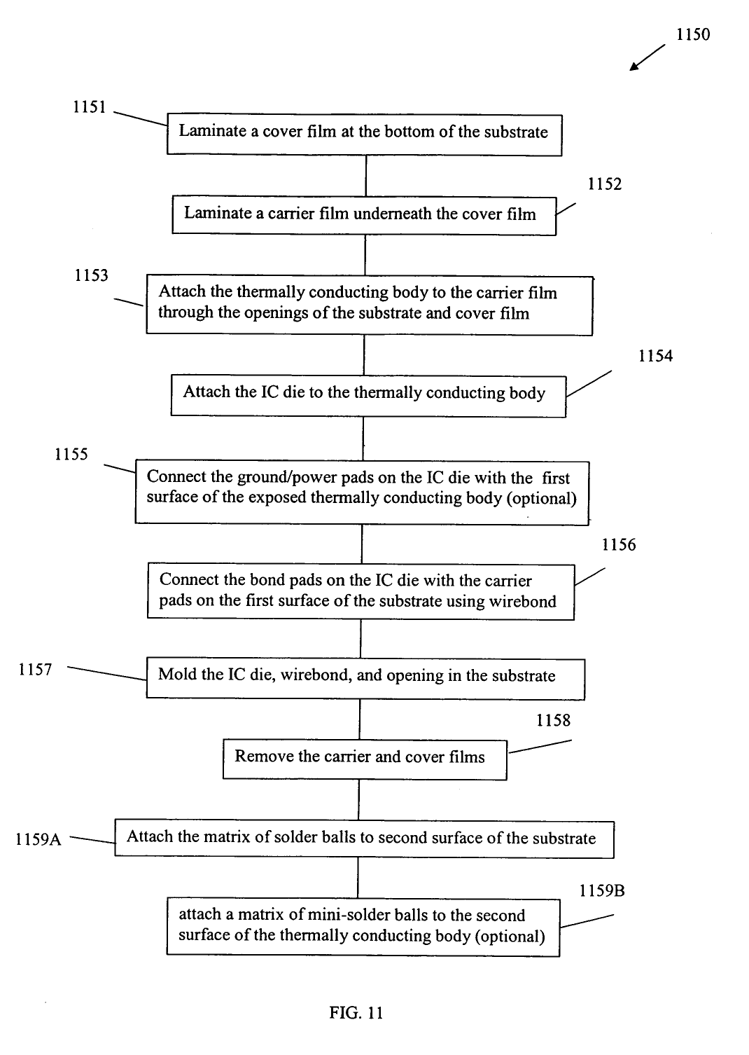

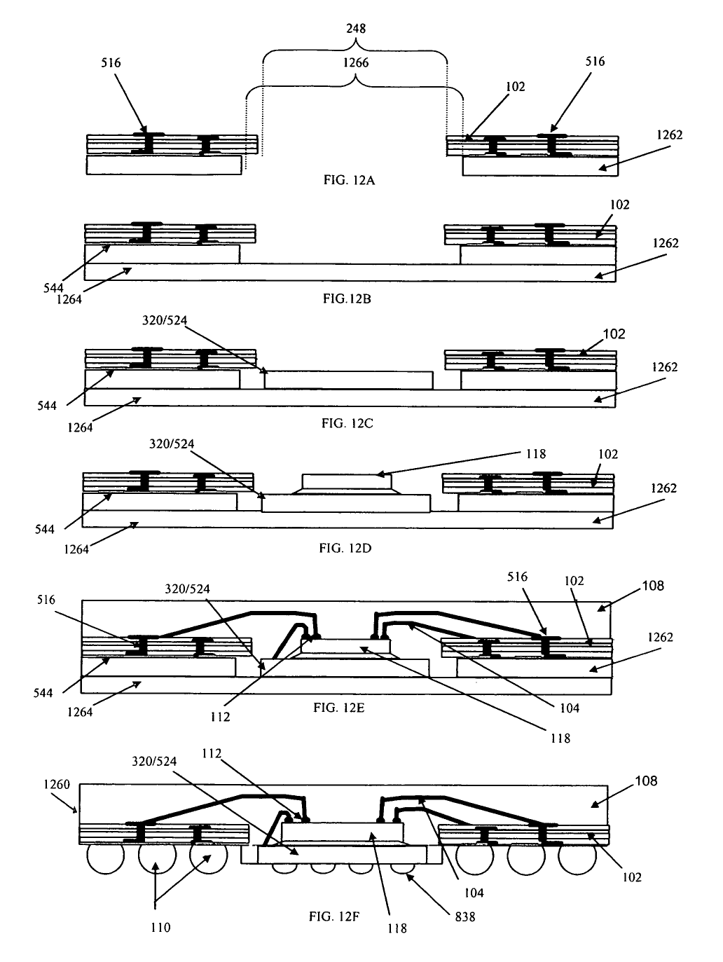

FIG. 11 shows a flowchart 1150 providing steps to assemble example die-up BGA packages, according to embodiments of the present invention. For example, flowchart 1150 may be used to assemble the packages shown in FIGS. 5, 7, and 9, described above. FIGS. 12A-12F illustrate assembly stages in a process for assembling an example die-up BGA package 1260 according to flowchart 1150, and are referred to in the description below regarding flowchart 1150, for illustrative purposes.

Flowchart 1150 begins in step 1151. In step 1151, a cover film is laminated at the bottom surface of a substrate. For example, as shown in FIG. 12A, cover film 1262 is laminated at the bottom surface (BGA side) of substrate 102 which has central window opening 248. Cover film 1262 also has a central window opening 1266 that may be larger than, smaller than, or the same size as opening 248 in substrate 102. Cover film 1262 provides a seal underneath substrate 102 during the mold encapsulation process of package assembly.

In step 1152, a carrier film is laminated underneath the cover film. For example, as shown in FIG. 12B, carrier film 1264 is laminated underneath cover film 1262. Carrier film 1264 provides a seal through window opening 1266 of the bottom surface of cover film 1262 for application of mold compound. Carrier film 1264 also provides temporary support and fixation of the heat spreader (e.g., thermally conductive body 524) and/or IC die position for the wirebond process. To this end, the top of carrier film 1264 may have an adhesive coating layer to hold the heat spreader and/or the IC die in place during the wirebond and mold encapsulation process.

In step 1153, the thermally conducting body is attached to the carrier film through the opening of the substrate and cover film. For example, as shown in FIG. 12C, the thermally conducting body, which may be either thermally conducting body 524 or thermally conducting body 320 for example, is attached to carrier film 1264 through central openings 248 and 1266 of substrate 102 and cover film 1262, respectively.

In step 1154, the IC die is attached to the thermally conducting body. For example, as shown in FIG. 12D, IC die 118 is attached to the thermally conducting body. Alternatively, IC die 118 could be attached to the thermally conducing body before the thermally conducting body is placed on carrier film 1264 for wire bonding.

In step 1155, the ground/power pads on the IC die are coupled to the exposed heat spreader using down-bond. For example, as shown in FIG. 12E, ground/power pads 112 on the IC die are connected to the exposed heat spreader 320/524 using down-bond.

In step 1156, the bond pads on the IC die are connected with the contact pads on top of the substrate using wirebond. For example, as also shown in FIG. 12E, bond pads 112 on IC die 118 are connected with contact pads 516 on top of substrate 102 using wirebond 104.

In step 1157, the IC die, wirebond, and opening are molded in the substrate. For example, also shown in FIG. 12E, IC die 118, wirebond 104, and opening 248 are molded in the substrate. Carrier film 1264 is supported during the wirebond process using a rigid platform. Alternatively, a reusable rigid supporting plate may be attached to the bottom surface of carrier film 1264 to provide support for IC die 118 and substrate 102 during the wirebond process. Wirebonds 104 and the active surface of IC die 118 are encapsulated from the environment-using a molding process.

In step 1158, the carrier and cover films are removed. For example, as shown in FIG. 12F, carrier film 1264 and cover film 1262 are removed.

In step 1159A, a matrix of solder balls is attached to the package substrate. For example, also shown in FIG. 12F, matrix of solder balls 110 is attached to package substrate 102.

In optional step 1159B (e.g., to construct package 800 shown in FIG. 8), a matrix of mini solder balls can be attached to the thermally conducting body. For example, also shown in FIG. 12F, matrix of mini solder balls 838 is attached to thermally conducting body 320/524.

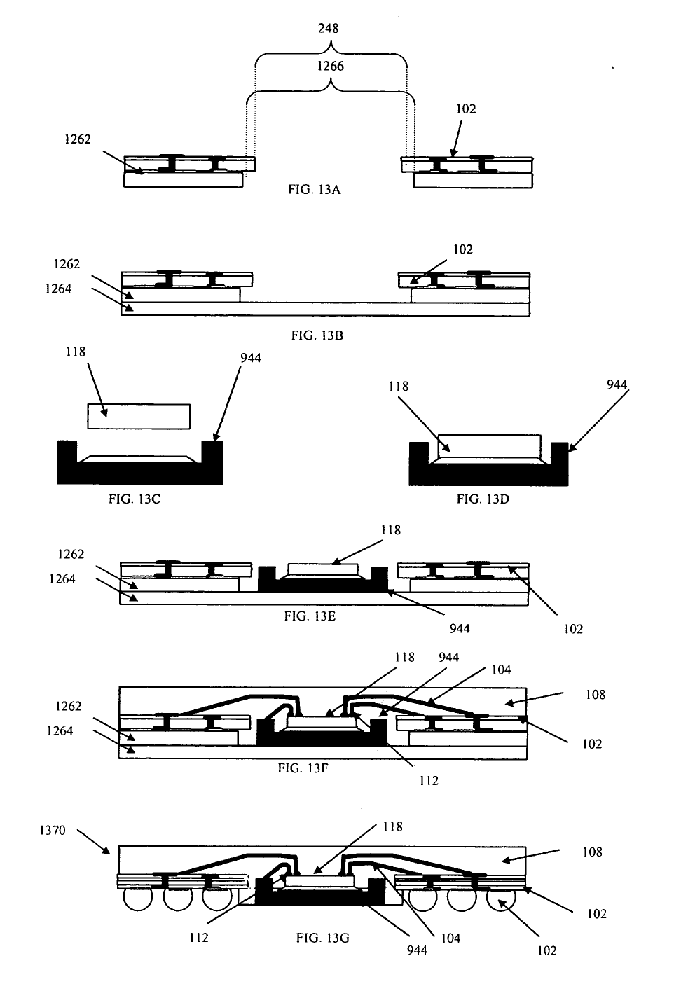

FIGS. 13A-13G illustrate assembly stages in a process for assembling an example die-up BGA package 1370 according to flowchart 1150. The stages shown in FIGS. 13A-13G are similar to those shown in FIGS. 12A-12F, with some of the differences noted as follows. In general, FIGS. 13A-13G show assembly of package 1370, with thermally conducting body 944 being incorporated into package 1370. FIGS. 13C and 13D indicate that IC die 118 can be attached to thermally conducting body 944 before thermally conducting body 944 is attached to the top surface of carrier film 1264 (as shown in FIG. 13E). Alternatively, IC die 118 can be attached to thermally conducting body 944 after thermally conducting body 944 is attached to the top surface of carrier film 1264.

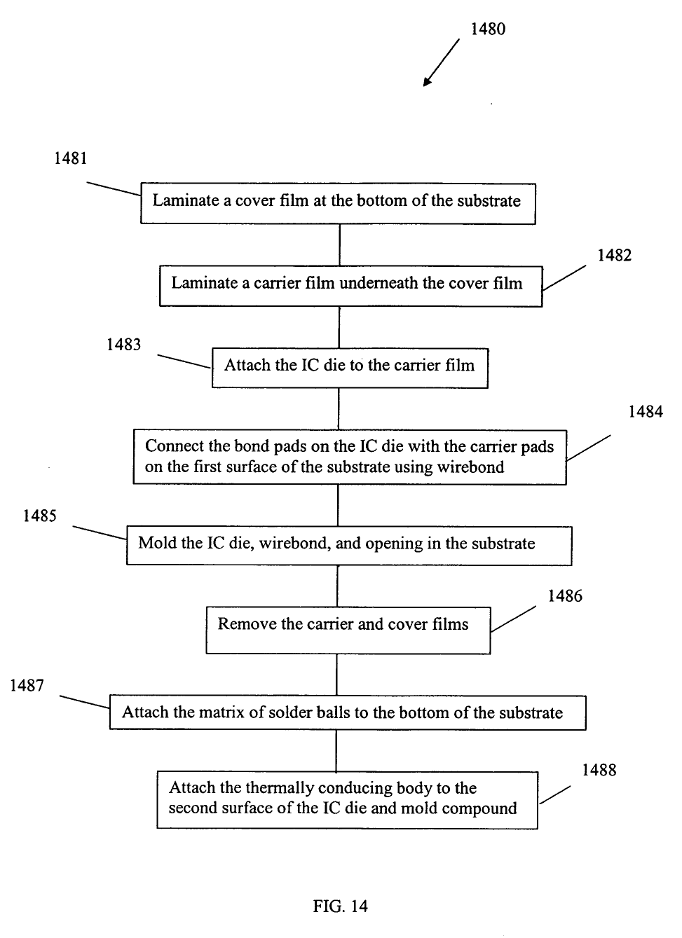

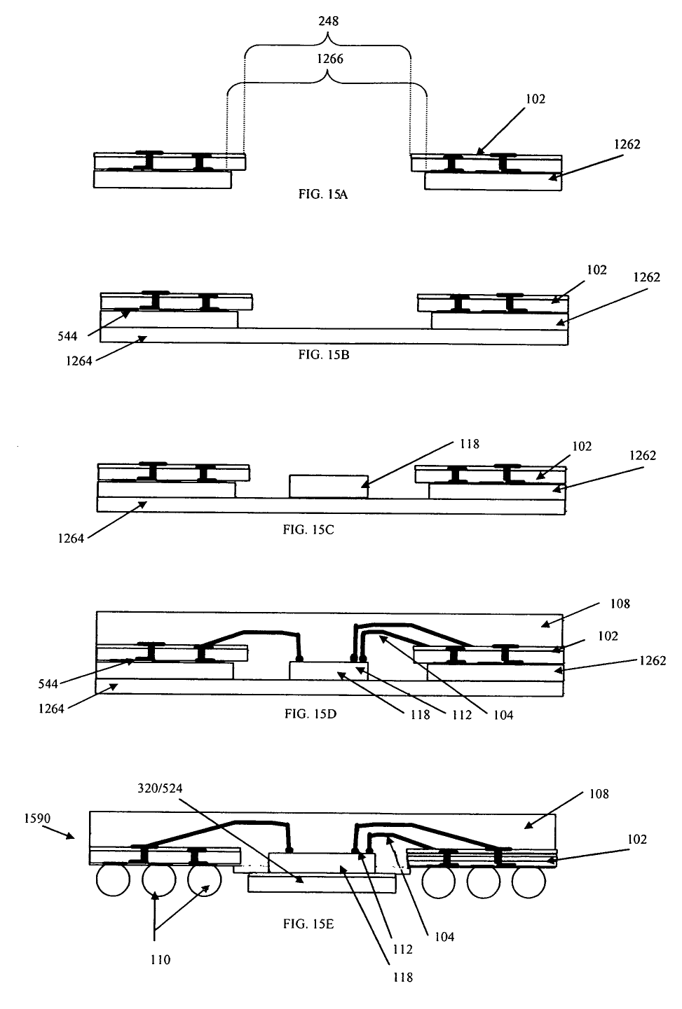

FIG. 14 shows a flowchart 1480 providing steps to assemble example die-up BGA packages, according to embodiments of the present invention. For example, flowchart 1480 may be used to assemble the package shown in FIG. 6, described above. FIGS. 15A-15E illustrate assembly stages in a process for assembling an example die-up BGA package 1590 according to flowchart 1480, and are referred to in the description below regarding flowchart 1480, for illustrative purposes.

Flowchart 1480 begins in step 1481. In step 1481, a cover film is laminated at the bottom surface of a substrate. For example, as shown in FIG. 15A, a cover film 1262 is laminated at the bottom surface of substrate 102, which has an opening 1266 that may be larger, same size, or smaller than opening 248 in substrate 102. Cover film 1262 provides a seal underneath substrate 102 during the mold encapsulation process of package assembly.

In step 1482, a carrier film is laminated underneath the cover film. For example, as shown in FIG. 15B, a carrier film 1264 is laminated underneath cover film 1262. Carrier film 1264 provides a seal through window opening 1266 of the bottom surface of cover film 1262 for application of molding compound. Carrier film 1264 also provides temporary support and fixation of the heat spreader or IC die position for the wirebond process. To this end, the top of carrier film 1264 may have an adhesive coating layer to hold the heat spreader or the IC die in place during the wirebond and mold encapsulation process.

In step 1483, the IC die is attached to the carrier film. For example, as shown in FIG. 15C, a bottom surface of IC die 118 is attached to the top surface of carrier film 1264.

In step 1484, the bond pads on the IC die are attached to the contact pads on the top surface of the substrate using wirebond. For example, as shown in FIG. 15D, bond pads 112 on IC die 118 are attached to contact pads 516 on the top surface of substrate 102 using wirebond 104.

In step 1485, the IC die, wirebond, and the opening in the substrate are molded using mold compound. For example, also shown in FIG. 15D, IC die 118, wirebond 104, and opening 248 in substrate 102 are molded using mold compound 108.

In step 1486, the carrier and cover films are removed. For example, as shown in FIG. 15E, carrier film 1264 and cover film 1262 are removed.

In step 1487, a matrix of solder balls is attached to the bottom surface of the substrate. For example, also shown in FIG. 15E, matrix of solder balls 110 is attached to solder ball pads 544 on the bottom surface of substrate 102.

In step 1488, a thermally conducing body is attached to the bottom surface of the IC die and mold compound. For example, also shown in FIG. 15E, thermally conducing body, which may be either thermally conducting body 524 or thermally conducting body 320, for example, is attached to the bottom surface of IC die 118 and mold compound 108. Steps 1488 and 1487 may be performed in either order.

### Example Advantages

Embodiments of the present invention provide many advantages over conventional BGA packages, including those described above with respect to FIGS. 1-4. Some of these advantages are described below. Each advantage described below does not necessarily apply to each embodiment described herein. Furthermore, the advantages provided by embodiments of the present invention are not necessarily limited to those described below.

(1) Placing the IC die in an opening in the substrate and reducing the length of wirebonds necessary to connect the IC die to the substrate substantially reduces the height of the package profile and increases reliability of the package as a whole.

(2) The die attach step used in a conventional die-up BGA package assembly process is not needed. Because of this, potential reliability issues associated with the die attach interface for conventional IC packages, such as both BGA and leadframe types, are removed. For example, an undesirable “popcorn phenomenon” may be conventionally caused by moisture absorption at room temperature and cracking at elevated temperature during a reflow surface mounting process, to release the build up of vapor pressure. The popcorn phenomenon may also conventionally occur where there exists insufficient die attach epoxy coverage underneath the die that could trap moisture as well as other foreign materials underneath the die. It is commonly known that die attach epoxy and organic substrates are widely used for IC package assembly. Moisture in the atmosphere is readily absorbed by both. The absorbed moisture penetrates into the die attach interface between the IC die and the substrate. When exposed to elevated temperature during reflow soldering, the absorbed moisture expands and creates high pressure at the die attach interface. If there is enough moisture, the die attach interface can crack and sometimes emit acoustic sounds like the popping of popcorn. An aspect of the present invention is to avoid the popcorn phenomenon by using metal or metal alloy for soldering the IC die and other components of an example package instead of die attach epoxy or organic substrates.

(3) There is no direct contact between the edges of the IC die and the inside walls of the substrate central window opening. The gaps are filled with molding compound that provides a buffer zone for thermal and mechanical stress interactions during manufacturing and applications between the IC die and the substrate. Package assembly/manufacturing yield and field application reliability can be improved due to the removal of the conventional contact interface between the IC die and the substrate.

(4) A mold compound covers the top surface of the substrate and may partially cover the bottom surface along the periphery of the substrate's window opening. This structure provides a tight locking mechanism between the substrate and the mold compound after mold cure. Bonding strength between the mold and the substrate is improved over the conventional mold structure, where the mold compound covers the top surface of the flat substrate only. Mechanical stresses are applied during the package singulation process. Mold delamination occurs due to mechanical stresses applied on the substrate, the mold, or both. Improved bonding between the mold and the substrate reduces mold delamination at the mold/substrate interfaces and improves production yield.

(5) Direct soldering of the thermally conducting body to the PWB for die-up wirebond packages improves package heat dissipation capability and provides electrical interconnection from the bottom surface of the IC die to the board. Package junction-to-board thermal resistance is substantially reduced using direct soldering of the thermally conducting body to application board during the surface mount process. The thermally conducting body acts as a heat spreader that provides extended heat dissipation surface for the IC die. The thermally conducting body also functions as a thermal connector that provides a heat dissipation path into PWB when soldered to the PWB. The thermally conducting body can be used as a ground or power plane by wirebond interconnection with the ground/power pad or pads on the IC die. Due to the short electrical path from the front side of the IC die to the ground or power plane on PWB, the impedance to current flow can be substantially reduced and power delivery to IC circuits improved.

(6) Mini solder balls attached to the exposed e-pad can have a different size and ball pitch from the solder balls attached to the package substrate surrounding the mini solder balls.

(7) Packages can use conventional types of substrate (i.e. organic, tape, ceramic, etc.) as well as advanced types of substrate (high density substrate, build-up substrate, Teflon substrate, etc.). A single routing layer substrate or a two or more layer substrate can be used.

(8) Various processes for die encapsulation can be used, including dam-and-fill (glob top), injection molding (over-mold, saw-singulated molding), among others, to meet the requirement of various applications and provide packages with various forms and appearances.

### CONCLUSION

While various embodiments of the present invention have been described above, it should be understood that they have been presented by way of example only, and not limitation. It should be apparent to persons skilled in the relevant art that various changes in form and detail can be made therein without departing from the spirit and scope of the present invention. Thus, the breadth and scope of the present invention should not be limited by any of the above-described exemplary embodiments, but should be defined only in accordance with the following claims and their equivalents.

What is claimed is:

1. An integrated circuit (IC) package, comprising:
a planar substrate having a plurality of contact pads on a first surface of the substrate electrically connected through the substrate to a plurality of solder ball pads on a second surface of the substrate, wherein the substrate has an opening formed through the substrate that is open at the first and second surfaces of the substrate;
an IC die positioned in the opening, wherein the IC die includes a plurality of bond pads and has opposing first and second surfaces;
a thermally conducting body having opposing first and second surfaces, wherein the IC die is mounted to the first surface of the thermally conducting body, and the second surface of the thermally conducting body is configured to be attached to a circuit board, wherein the thermally conducting body is not in direct contact with the substrate;
a wire bond that connects a bond pad of the IC die and a contact pad of the substrate;
a mold compound that seals the IC die, the wirebond, and the opening in the substrate; and
a plurality of solder balls coupled to the solder ball pads on the second surface of the substrate.

2. The package of claim 1, further comprising a second wire bond that connects a second bond pad of the IC die and the thermally conducting body.

3. The package of claim 1, wherein the thermally conducting body is planar.

4. The package of claim 1, wherein the thermally conducting body is coated with a metal.

5. The package of claim 1, wherein a standoff height of the thermally conducting body less than or equal to a diameter of a solder ball of the plurality of solder balls.

6. The package of claim 1, wherein the thermally conducting body is electrically conductive.

7. The package of claim 1, wherein a width of the thermally conducting body is less than a width of the IC die.

8. The package of claim 1, wherein a width of the thermally conducting body is greater than a width of the IC die.

9. The package of claim 1, wherein a width of the thermally conducting body is substantially equal to a width of the IC die.

10. The package of claim 1, wherein a width of the thermally conducting body is less than a width of the opening in the substrate.

11. The package of claim 1, wherein a width of the thermally conducting body is greater than a width of the opening in the substrate.

12. The package of claim 1, wherein a width of the thermally conducting body is substantially equal to a width of the opening in the substrate.

13. The package of claim 1, wherein side walls of the thermally conducting body are at least partially exposed.

14. The package of claim 1, further comprising:
a second plurality of solder balls attached to the second surface of the thermally conducting body.

15. The package of claim 14, wherein a diameter of solder balls of the first plurality of solder balls is greater than a diameter of solder balls of the second plurality of solder balls.

16. The package of claim 1, wherein the thermally conducting body is non-planar.

17. The package of claim 16, wherein the thermally conducting body includes a cavity, wherein the IC die is mounted to the thermally conducting body in the cavity.

18. A method for forming an integrated circuit (IC) package, comprising:
receiving a substrate having a plurality of contact pads on a first surface of the substrate coupled through the substrate to a plurality of solder ball pads on a second surface of the substrate, wherein the substrate has an opening formed through the substrate that is open at the first and the second surfaces of the substrate;
mounting an IC die to a first surface of a thermally conducting body, wherein the IC die includes a plurality of bond pads;
positioning the thermally conducting body in the opening, wherein the second surface of the thermally conducting body is configured to be attached to a circuit board, wherein the thermally conducting body is not in direct contact with the substrate;
connecting a bond pad of the IC die and a contact pad of the substrate using a wire bond;
sealing the IC die, the wirebond, and the opening in the substrate using a mold compound; and
attaching a plurality of solder balls to the solder ball pads on the second surface of the substrate.

19. The method of claim 18, further comprising:
coating at least a portion of the thermally conducting body with a metal.

20. The method of claim 18, further comprising:
forming the plurality of solder balls such that a standoff height of the thermally conducting body is less than or equal to a diameter of a solder ball in the plurality of solder balls.

21. The method of claim 18, wherein said connecting step comprises:
coupling the thermally conducting body to a ground pad or a power bond pad of the IC die.

22. The method of claim 18, further comprising:
forming the thermally conducting body to have a width less than a width of the IC die.

23. The method of claim 18, further comprising:
forming the thermally conducting body to have a width greater than a width of the IC die.

24. The method of claim 18, further comprising:
forming the thermally conducting body to have a width substantially equal to a width of the IC die.

25. The method of claim 18, further comprising:
forming the thermally conducting body to have a width less than a width of the opening in the substrate.

26. The method of claim 18, further comprising:
forming the thermally conducting body to have a width greater than a width of the opening in the substrate.

27. The method of claim 18, further comprising:
forming the thermally conducting body to have a width substantially equal to a width of the opening in the substrate.

28. The method of claim 18, wherein the thermally conducting body has peripheral side walls, further comprising:
exposing at least a portion of the side walls of the thermally conducting body.

29. The method of claim 18, further comprising:
attaching a second plurality of solder balls to the second surface of the thermally conducting body.

30. The method of claim 29, further comprising:
forming the solder balls of the second plurality of solder balls to have diameters that are less than diameters of solder balls of the first plurality of solder balls.

31. The method of claim 18, further comprising:
forming a cavity in the thermally conducting body;
wherein said mounting step comprises:
mounting the IC die in the cavity.

32. The method of claim 18, further comprising:
connecting a second bond pad of the IC die and the thermally conducting body using a second wire bond.

33. A method of constructing an integrated circuit (IC) ball grid array packaging apparatus, comprising:
attaching a cover film to a substrate, wherein an opening through the cover film substantially coincides with an opening through the substrate;
attaching a carrier film to the cover film;
attaching a thermally conducting body to the carrier film through the opening of the substrate and the opening of the cover film, wherein the thermally conducting body is not in direct contact with the substrate;
attaching an IC die to the thermally conducting body;
connecting bond pads on the IC die with contact pads on the substrate using a plurality of wirebonds;
sealing the IC die, the wirebonds, and the opening in the substrate using a mold compound;
removing the carrier film and the cover film; and
attaching a plurality of solder balls to the substrate.

34. The method of claim 33, further comprising:
performing attachment of the IC die to the thermally conducting body before performing attachment of the thermally conducting body to the carrier film.

35. The method of claim 33, further comprising:
attaching a second plurality of solder balls to the thermally conducting body.

36. The method of claim 33, further comprising:
connecting a bond pad on the IC die with the thermally conducting body using a wirebond.

37. A method of assembling an integrated circuit (IC) package, comprising:
attaching a cover film to a substrate, wherein an opening through the cover film substantially coincides with an opening through the substrate;
attaching a carrier film to the cover film;
attaching an IC die to the carrier film in the opening;
attaching bond pads of the IC die to contact pads on the substrate using a plurality of wirebonds;
sealing the IC die, the wirebonds, and the opening in the substrate using a mold compound;
removing the carrier film and the cover film;
attaching a first plurality of solder balls to the substrate; and
attaching a thermally conducting body to the IC die and the mold compound such that the thermally conducting body is not in direct contact with the substrate.
